(19) United States
(12) Patent Application Publication
(10) Pub. No.: US 2009/0126776 A1
(43) Pub. Date: May 21, 2009

(54) Radiation Concentrating Device

(76) Inventors: Sergio Molon, Merano (IT); Alfredo Maglione, Povo (IT)

Correspondence Address: Modiano & Associati;Via Meravigli 16, 20123 Milan, Milan, IT

(21) Appl. No.: 12/226,414

(22) PCT Filed: Apr. 23, 2007
(86) PCT No.: PCT/EP2007/003547

§ 371 Date: Oct. 17, 2008

(30) Foreign Application Priority Data
Apr. 24, 2006 (IT) PD2006A000153

(51) Int. Cl. H01L 31/052

(52) U.S. Cl. 136/246

(57) ABSTRACT

A radiation concentrating device, comprising a substantially parabolic mirror, which is adapted to reflect the energy radiation or electromagnetic radiation that reaches it so as to converge toward an active area of a receiving element arranged in front, the active area being interposed between the focal point of the mirror and the mirror itself, the mirror and the receiving element being fixed by way of coupling elements to a same base. The transverse dimension of the active area is smaller than the transverse dimension of the mirror arranged in front. The base is preset to support a plurality of parabolic mirrors and corresponding receiving elements, which are mutually connected by conductors.

The present invention relates to a radiation concentrating device.

### BACKGROUND OF THE INVENTION

Radiation concentrating devices are currently known particularly for use in the provision of solar or photovoltaic panels.

In a first type of these concentrating devices, the function of concentrating element is performed by a Fresnel lens or variations thereof.

The Fresnel lens is arranged between the sunlight source and the focal point of the photovoltaic cell.

This first type of Fresnel-lens concentrating device generally entails important energy losses between 10% and 20% due to limited transmittance.

Further, the precision of the focus generated by a Fresnel lens is limited to a few spectral lines and is affected by substantial chromatic aberration which impairs the efficiency of the concentrating device; in order to obviate this problem, generally the dimensions of the receiver (sensor or transducer) associated with the lens are increased, with a consequent overall increase in the production costs of the device.

A second type of concentrating device has a parabolic mirror with a longitudinal focus, i.e., a focus which is distributed along a line or band which is substantially straight, and therefore requires solar cells which are assembled in mutually adjacent rows along the directrix of the focus, with consequent problems linked to dissipation of the heat accumulated by the cells and by the supports on which they are mounted.

Further, for both of these types of known concentrating device, the concentrating element, mirror or Fresnel lens, and the receiving element are mounted separately on separate supports, which must be then mutually positioned laboriously and with the appropriate skill in order to allow correct redirection of the radiation toward the active area of the receiving element.

### SUMMARY OF THE INVENTION

The aim of the present invention is to provide a radiation concentrating device which is capable of obviating the drawbacks shown by known types of concentrating device.

Within this aim, an object of the present invention is to provide a concentrating device which has a higher efficiency than known devices.

Another object of the present invention is to provide a concentrating device in which the heat accumulation can be dissipated more efficiently than in known types of device.

Another object of the present invention is to provide a concentrating device which can be assembled more rapidly and at least as accurately as known types of concentrating device.

A further object of the present invention is to provide a concentrating device particularly but not exclusively adapted for providing solar or photovoltaic panels.

A still further object of the present invention is to provide a radiation concentrating device which can be manufactured with known systems and technologies.

This aim and these and other objects, which will become better apparent hereinafter, are achieved by a radiation concentrating device, characterized in that it comprises a substantially parabolic mirror, which is adapted to reflect the energy radiation or electromagnetic radiation that reaches it so as to converge toward an active area of a receiving element arranged in front, said active area being interposed between the focal point of said mirror and the mirror itself, said mirror and said receiving element being fixed by way of coupling means to a same base.

### BRIEF DESCRIPTION OF THE DRAWINGS

Further characteristics and advantages of the invention will become better apparent from the following detailed description of three preferred but not exclusive embodiments thereof, illustrated by way of non-limiting example in the accompanying drawings, wherein:

FIG. 1 is a sectional side view of a device according to the invention in a first embodiment;

FIG. 2 is a top view of the device according to the invention in a second embodiment;

FIG. 3 is a side view of the device according to the invention, in the second embodiment, provided with a plurality of mirrors along a line, with the respective receiving elements;

FIG. 4 is another top view of the device according to the invention in the second embodiment, composed of a plurality of mirrors sorted by rows and columns;

FIG. 5 is a sectional side view of the device according to the invention in a third embodiment;

FIG. 6 is a front view of the device of FIG. 5.

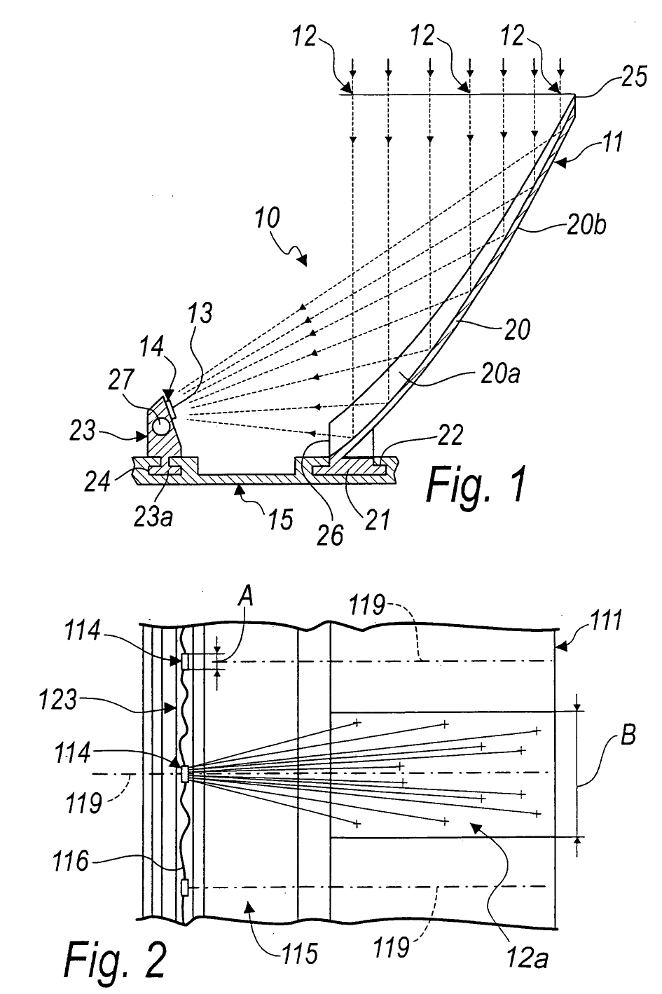

### DESCRIPTION OF THE PREFERRED EMBODIMENTS

With reference to the figures, a radiation concentrating device according to the invention is generally designated by the reference numeral 10 in its first embodiment.

The concentrating device 10 comprises, in its minimum configuration, a substantially parabolic mirror 11, which is designed to reflect the energy radiation or electromagnetic radiation that reaches it, designated schematically by lines 12, so that it converges toward an active area 13 of a receiving element 14 arranged in front.

The active area 13 is interposed between the focal point of the mirror 11 and the mirror 11 itself.

The substantially parabolic mirror 11 is shaped like a sector of a paraboloid formed by the rotation of a parabola about its own axis of symmetry.

The mirror 11 and the receiving element 14 are fixed by way of coupling means, described in greater detail hereinafter, to a same base 15.

The active area 13 of the receiving element 14 has a transverse dimension A which is smaller than a transverse dimension B of the mirror 11 arranged in front.

In the exemplary embodiments of the invention described here by way of non-limiting example, the active area 13 is substantially quadrangular and has a much smaller transverse dimension A than the corresponding transverse dimension B of the mirror 11, which also has a rectangular profile in plan view.

Therefore, the active receiving area 13 is such as to collect the radiation reflected by the mirror 11, which is in any case made to converge by the mirror 11 toward a region which is contained in the neighborhood of the central axis of the mirror 11.

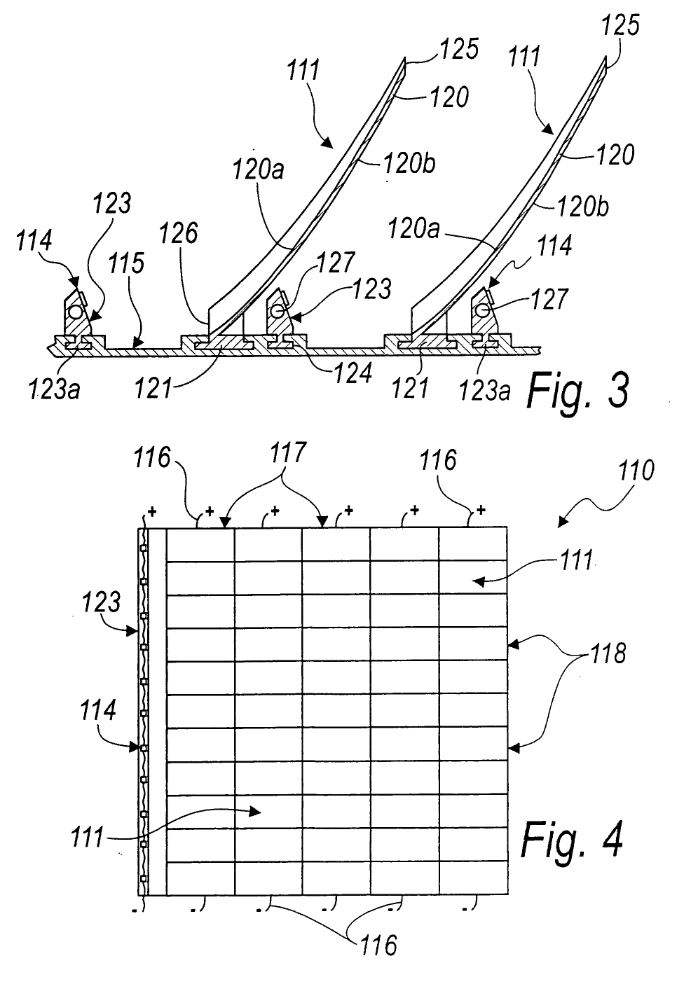

In a second embodiment of the device, designated by the reference numeral 110 in FIGS. 2, 3 and 4, the base 115 is designed to support a plurality of parabolic mirrors 111 and corresponding receiving elements 114 which are mutually connected by means of conductors 116.

The parabolic mirrors 111 and the respective receiving elements 114 are arranged side by side so as to form parallel and adjacent rows 117 and laterally adjacent lines 118.

Each receiving element 114, except for the ones arranged on the outer perimeter of the base 115, is arranged proximate to the back 120b of the next neighboring mirror 111, which lies above it.

In FIG. 2, the radiation reflected toward the receiving element 114 is designated by the reference numeral 12a.

As mentioned, the mirrors 111 are arranged advantageously in rows 117 and lines 118 so as to affect continuously, with respect to a direction which is perpendicular to the arrangement of the base 115, the area covered by the base 115 on which they are fitted; in this manner, the mirrors 111 catch all of the radiation that arrives on them at right angles to the base 115 and the surface for collecting the radiation 12 is maximized.

Conveniently, for this purpose, the upper end edges 25 and 125 and the lower end edges 26 and 126 of a mirror 11 and 111 are cut along a direction which is parallel to the direction of the radiation 12.

The receiving elements 14 and 114 can be sensors, transducers or photovoltaic cells and in general sensors which are sensitive to electromagnetic radiation.

In particular, the receiving elements 14 and 114 can be sensors for detecting analog or digital signals.

The receiving elements 14 and 114 must be positioned along the longitudinal central axis 119 of the corresponding mirror 111.

Each mirror 11 and 111 is constituted by a parabolic body 20 and 120, the concave face 20a and 120a of which is coated with optical-grade reflective material.

The parabolic body 20 and 120 is made of metallic material, plastic material, ceramic material or composite materials; depending on the electromagnetic band that must be captured by the device 10 and 110, the mirror is provided and coated with the material that is most suitable to obtain the best index of reflectance.

In particular, the curvature of the parabola that defines the paraboloid of which the mirror 11 and 111 is a sector is calculated with the equation y=Ax²+Bx+C, in which the parameter A is comprised between 0 and 10, the parameter B is comprised between 0 and 10, and the parameter C is comprised between −100 and +100.

The means for coupling the mirror 11 and 111 to the base 15 and 115 are provided by a lower portion 21 and 121 of the body 20 and 120 of the mirror, which is contoured so as to be inserted in a complementary shaped seat 22 and 122 provided on the base 15 and 115.

Likewise, the means for coupling the receiving element 14 and 114 to the base 15 and 115 are constituted by a support 23 and 123 for said receiving element; below the support 23 and 123 there is a portion 23a and 123a which is contoured so as to be inserted in a complementary shaped seat 24 and 124 provided on the base 15 and 115.

The support 23 and 123 is made of a material which is capable of dissipating the excess heat from the supported receiving element 14 and 114.

The lower portions 21, 23a, 121 and 123a respectively of the body 20 and 120 of the mirror and of the support 23 and 123 are substantially T-shaped and are adapted to be inserted in the corresponding seats 22, 24, 122 and 124, which are formed by complementarily shaped slots which can be accessed from one side of the base 15 and 115.

In this manner, the assembly of the device 110 according to the invention is very simple, quick and precise; the base 115 on which the slots for the lower portions 21, 23a, 121 and 123a are formed is in fact provided monolithically, and mounting the mirrors and receiving elements thereon requires only the insertion of said lower portions in the respective slots, without any other long and meticulous maneuvers for seeking the optimum mutual arrangement of the mirrors and the corresponding receiving elements.

The support 23 and 123 for the receiving element 14 and 114 has a through hole 27 and 127 for the flow therein of coolant liquid for energy recovery of heat, if the device 10 and 110 according to the invention is used for example to provide a solar panel.

The device 10 and 110, if used to provide solar or photovoltaic panels, comprises means, not shown for the sake of simplicity, for following automatically the source of the radiation 12 in order to vary the trim of said device, since the radiation 12 must reach the mirrors with a constant angle.

The device 10 and 110 according to the invention can be assembled easily in a modular manner together with other identical devices to provide panels of any size according to requirements.

A known type of these follower means can be for example a heliostat.

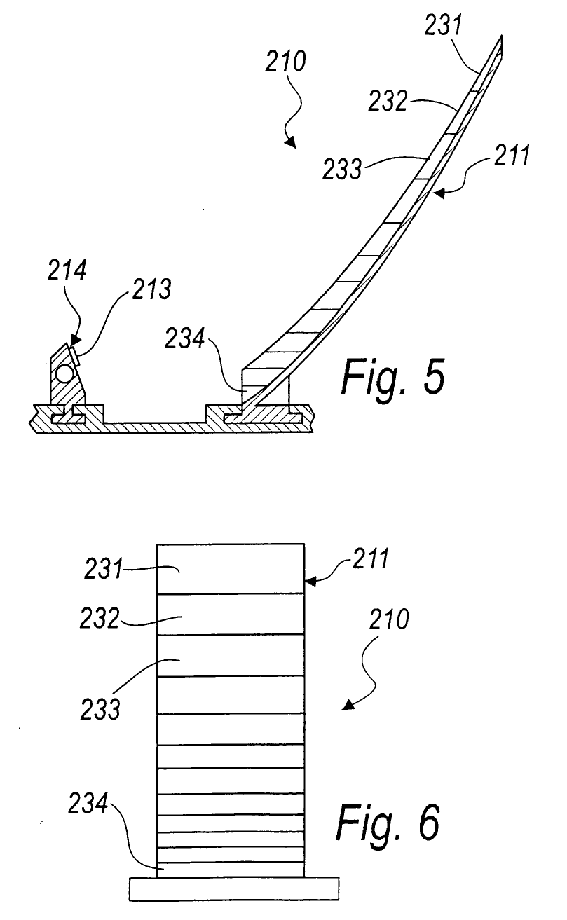

In a third embodiment of the invention, shown in FIGS. 5 and 6 and designated therein by the reference numeral 210, the substantially parabolic mirror 211 is composed of a plurality of reflective elements arranged side by side, of which the figure illustrates by way of example the ones designated by the reference numerals 231, 232, 233 and 234.

The reflective elements 231, 232, 233 and 234, while not providing an exactly parabolic mirror 211, approximate its contour and perform the same function thereof of reflecting radiation toward a same active receiving area 213 of the receiving element 214.

The individual reflective elements 231, 232, 233 and 234, while not reflecting toward a same focal point, in any case direct the reflected radiation toward the same area 213.

Equivalently and as an alternative, the mirror 211 can be provided with machinings, micromachinings and surface treatments such as to no longer have a single continuous reflective surface but a plurality of reflective elements which form a discontinuous reflective surface.

In practice it has been found that the invention thus described solves the problems noted in known types of radiation concentrating device.

In particular, the present invention provides a concentrating device which has a higher efficiency than known devices: the absence of lenses and in particular of Fresnel lenses in fact improves transmittance and eliminates the problem of chromatic aberration which is typical of lenses.

Moreover, the present invention provides a concentrating device in which thermal accumulation can be dissipated more efficiently than in known types of device, by virtue of the through hole on the support for the receiving elements, inside which it is possible to circulate a transfer fluid for dissipating the accumulated heat.

Further, the present invention provides a concentrating device which can be assembled more rapidly and at least as accurately as known types of concentrating device.

Moreover, the present invention provides a radiation concentrating device which is particularly but not exclusively suitable to provide solar or photovoltaic panels.

Moreover, the present invention provides a radiation concentrating device which can be manufactured with known systems and technologies.

The invention thus conceived is susceptible of numerous modifications and variations, all of which are within the scope of the appended claims; all the details may further be replaced with other technically equivalent elements.

In practice, the materials employed, so long as they are compatible with the specific use, as well as the dimensions, may be any according to requirements and to the state of the art.

The disclosures in Italian Patent Application No. PD2006A000153 from which this application claims priority are incorporated herein by reference.

What is claimed is:

1-23. (canceled)

24. A radiation concentrating device, comprising a substantially parabolic mirror, which is adapted to reflect energy radiation or electromagnetic radiation that reaches it so as to converge toward an active area of a receiving element arranged in front, said active area being interposed between a focal point of the mirror and said mirror, said mirror and said receiving element being fixed by way of coupling means to a same base.

25. The device of claim 24, wherein said active area has a transverse dimension which is smaller than a transverse dimension of the mirror arranged in front.

26. The device of claim 24, wherein said substantially parabolic mirror is shaped like a sector of a paraboloid which is defined by the rotation of a parabola about an axis which passes through a focal point of said parabola.

27. The device of claim 24, wherein said base is. designed to support a plurality of parabolic mirrors and corresponding receiving elements which are mutually connected by means of conductors.

28. The device of claim 27, wherein said parabolic mirrors and the respective receiving elements are arranged side by side so as to form parallel and adjacent rows and parallel and adjacent lines.

29. The device of claim 27, wherein each receiving element, except for the ones arranged on an outside perimeter of the base, is arranged proximate to a back of a nearby subsequent mirror, which lies above it.

30. The device of claim 28, wherein said mirrors are arranged in rows and lines so as to affect with continuity, with respect to a direction which is perpendicular to the arrangement of the base, the area covered by the base on which they are mounted, so as to collect all of the radiation that reaches the base at right angles thereto and so as to maximize the surface for collecting radiation.

31. The device of claim 28, wherein said receiving elements are selectively sensors, transducers or photovoltaic cells.

32. The device of claim 31, wherein said receiving elements are sensors for detecting analog or digital signals.

33. The device of claim 30, wherein said receiving elements are sensors which are sensitive to electromagnetic radiation.

34. The device of claim 28, wherein said receiving elements are arranged along a longitudinal central axis of the corresponding mirror.

35. The device of claim 24, wherein a mirror is constituted by a body whose concave face is lined with optical-grade reflective material.

36. The device of claim 35, wherein said body is made of metallic material, plastic material, ceramic material or composite materials.

37. The device of claim 26, wherein the curvature of the parabola that forms the paraboloid of which said mirror is a sector is calculated with the equation y=Ax²+Bx+C, in which parameter A is comprised between 0 and 10, parameter B is comprised between 0 and 10, and parameter C is comprised between −100 and +100.

38. The device of claim 35, wherein said means for coupling a mirror to the base are constituted by a lower portion of the body of the mirror, which is contoured so as to be inserted in a complementary shaped seat provided on said base.

39. The device of claim 38, wherein said means for coupling a receiving element to the base are constituted by a support for said element, below which there is a portion which is contoured so as to be inserted in a complementarily shaped seat provided on said base.

40. The device of claim 39, wherein said support is made of a material which is capable of dissipating the excess heat from the supported receiving element.

41. The device of claim 39, wherein said lower portions of the body of the mirror and of the support for a receiving element are substantially T-shaped and are adapted to be inserted in the corresponding seats formed by complementarily shaped slots which can be accessed from one side of the base.

42. The device of claim 24, wherein an upper end edge and a lower end edge of the mirror are truncated along a direction which is parallel to a direction of the radiation.

43. The device of claim 39, wherein said support for a receiving element has a through hole for the flow of a coolant liquid for the energy recovery of heat.

44. The device of claim 24, further comprising means for automatically following the source of the radiation in order to vary the trim of said device.

45. The device of claim 24, wherein said substantially parabolic mirror is composed of a plurality of reflective elements arranged side-by-side, said reflective elements being contoured so as to approximate the shape of a parabolic sector and being adapted to perform its same function of reflecting radiation toward a same active receiving area of a receiving element arranged in front.

46. The device of claim 45, wherein the substantially parabolic mirror can be provided by means of machinings, micromachinings and surface treatments so as to have a reflective surface which is no longer unique and continuous but a plurality of reflective elements which form a discontinuous reflective surface.
